(19) United States
(12) Patent Application Publication
(10) Pub. No.: US 2024/0021434 A1
(43) Pub. Date: Jan. 18, 2024

(54) METHOD FOR IMPROVING HEIGHT DIFFERENCE BETWEEN GATES

(71) Applicant: Shanghai Huali Integrated Circuit Corporation, Shanghai (CN)

(72) Inventor: Jian Zhang, Shanghai (CN)

(21) Appl. No.: 18/129,433

(22) Filed: Mar. 31, 2023

(30) Foreign Application Priority Data
Jul. 12, 2022 (CN) 202210817435.X

(51) Int. Cl. H01L 21/321; H01L 21/3105

(52) U.S. Cl. CPC H01L 21/3212; H01L 21/31053

(57) ABSTRACT

A method for improving a height difference between gates comprises steps of: forming small-size and large-size dummy gate structures on a substrate; forming a silicon nitride layer on the gates; depositing an interlayer dielectric layer on the silicon nitride layer; polishing the interlayer dielectric layer until the top surfaces of the large-size dummy gate structures are approximately 110 Å more than the top surface of the small-size dummy gate structures; removing the small-size and large-size dummy gate structures to form trenches, the height of the silicon nitride layer on sidewalls of the trenches is the same as the height of the adjacent interlayer dielectric layer; depositing an aluminum layer to fill the trenches and cover the dielectric material on the top surface of interlayer dielectric layer.

### CROSS-REFERENCES TO RELATED APPLICATIONS

This application claims priority to Chinese patent application No. CN 202210817435.X, filed on Jul. 12, 2022 at CNIPA, and entitled “METHOD FOR IMPROVING HEIGHT DIFFERENCE BETWEEN GATES”, the disclosure of which is incorporated herein by reference in entirety.

### TECHNICAL FIELD

The present application relates to the field of semiconductor technology, in particular, to a method for improving a height difference between gates.

### BACKGROUND

Since the Metal Gate (MG) process was introduced into the process note of 28 nm high-k dielectric gate, the necessary metal gate chemical-mechanical polishing has been added, which has led to an increase in the height differences between large-size and small-size gates. Because of the characteristics of the chemical-mechanical polishing when applied for polishing metal gates, polishing speed of large-size gate area is faster than that of small-size gate area, so the current polishing process often induces a height difference of more than 200 Å. When the post polish height of large-size gates is lower, it brings one of the bottlenecks to the improvement of device performance.

At present, two solutions have been used to solve the problem caused by the lower height of large-size gates. First, reduce metal gates polishing time during chemical-mechanical polishing, because the less they are polished, the smaller the height loss will be. Second, large-size gates are made taller in advance through some new process to make up for the loss of the large-size metal gates caused by chemical-mechanical polishing.

There are three factors determine the height of gates in the current process: polishing of the InterLayer Dielectric (ILD) layer, etching removal of the dummy gates, and metal gates polishing. Among the three factors, the etching removal of the dummy gates plays the leading role.

### BRIEF SUMMARY

The present application provides a method for improving a height difference between gates, wherein the method at least includes:

step 1: providing a silicon substrate, forming small-size dummy gate structures and large-size dummy gate structures adjacent to the small-size dummy gate structures on the silicon substrate, wherein the height of the small-size dummy gate structures is the same as the height of the large-size dummy gate structures; then forming a silicon nitride layer on surfaces of both the small-size dummy gate structures and the large-size dummy gate structures; then depositing an interlayer dielectric layer on the silicon nitride layer on both the small-size dummy gate structures and the large-size dummy gate structures, wherein the interlayer dielectric layer fills gaps between the small-size dummy gate structures and the large-size dummy gate structures;

step 2: polishing the interlayer dielectric layer until the top surface of the large-size dummy gate structures is higher than the top surface of the small-size dummy gate structures by H1, the H1 is approximately 110 Å;

step 3: removing the small-size dummy gate structures and the large-size dummy gate structures to form small-size trenches and large-size trenches, so the top surfaces of the silicon nitride layer remaining on the sidewalls of the large-size trenches and the small-size trenches are the same as the top surface of the interlayer dielectric layer;

step 4: depositing a dielectric material on the bottom surfaces and the sidewalls of the large-size trenches and the small-size trenches, and the top surface of the interlayer dielectric layer;

step 5: depositing an aluminum layer to fill the large-size trenches and the small-size trenches and also cover the top surface of the dielectric material of the interlayer dielectric layer; and

step 6: performing chemical-mechanical polishing on the aluminum layer until the top surface of the aluminum layer in the large-sized trenches is lower than the top surface of the aluminum layer in the small-sized trenches by H2 after the dielectric material on the interlayer dielectric layer is removed, the H2 is approximately 50 Å.

Exemplarily, in step 1, the dimension of the small-size dummy gate structures is less than 200 nm; the dimension of the large-size dummy gate structures is more than 200 nm.

Exemplarily, in step 1, the number of the small-size dummy gate structures and the number of the large-size dummy gate structures are respectively plurality, and the plurality of small-size dummy gate structures are spaced, the plurality of large-size dummy gate structures are spaced, and the plurality of small-size dummy gate structures are disposed on one side of the plurality of large-size dummy gate structures.

Exemplarily, in step 1, the small-size dummy gate structures and the large-size dummy gate structures are formed of polysilicon.

Exemplarily, in step 2, the method for polishing the interlayer dielectric layer is a chemical-mechanical polishing method.

Exemplarily, in step 3, the dimension of the large-sized trenches is more than 200 nm; the dimension of the small-size trenches is less than 200 nm.

Exemplarily, in step 4, the dielectric material includes tungsten.

Exemplarily, in step 6, after the chemical-mechanical polishing is performed on the aluminum layer, the aluminum layer, the dielectric material and the silicon nitride layer in the large-size trenches form large-size metal gates; the aluminum layer, the dielectric material and the silicon nitride layer in the small-size trenches form small-size metal gates.

Exemplarily, in step 6, after the polishing is performed, the heights of the large-size metal gates are approximately 361 Å; the heights of the small-size metal gates are approximately 415 Å.

As described above, the method of improving a height difference between gates provided by the present application has the following beneficial effects: in the present application, by polishing the interlayer dielectric layer to enable the height of the large-size dummy gates to be approximately 100 Å more than the height of the small-size dummy gates, since the height of the metal gates to be designed is not continuously reduced in the dummy gate removal process, no pit is caused between the upper surface of the remaining interlayer dielectric layer and the adjacent silicon nitride layer, thus shortening the subsequent polishing time of the metal gates, reducing the height difference between the large-size metal gates and the small-size metal gates, and helping to improve the device performance.

### BRIEF DESCRIPTION OF THE DRAWINGS

FIG. 1 illustrates a cross sectional view of a structure of mixed large-size dummy gate structures and small-size dummy gate structures on a substrate according to the present application.

FIG. 2 illustrates a cross sectional view of a structure after an interlayer dielectric layer is polished in step 2 according to the present application.

FIG. 3 illustrates a cross sectional view of a structure after large-size dummy gate structures and small-size dummy gate structures are removed according to the present application.

FIG. 4 illustrates a cross sectional view of a structure of metal gates formed in large-size trenches and small-size trenches according to the present application.

FIG. 5 illustrates the flowchart of a method for improving the height difference between gates according to the present application.

### DETAILED DESCRIPTION OF THE APPLICATION

The embodiments of the present application will be described below through specific examples. Those skilled in the art can easily understand other advantages and effects of the present application from the content disclosed in the description. The present application may also be implemented or applied in other specific ways. The details in the description may also be modified or changed based on different views and applications without departing from the spirit of the present application.

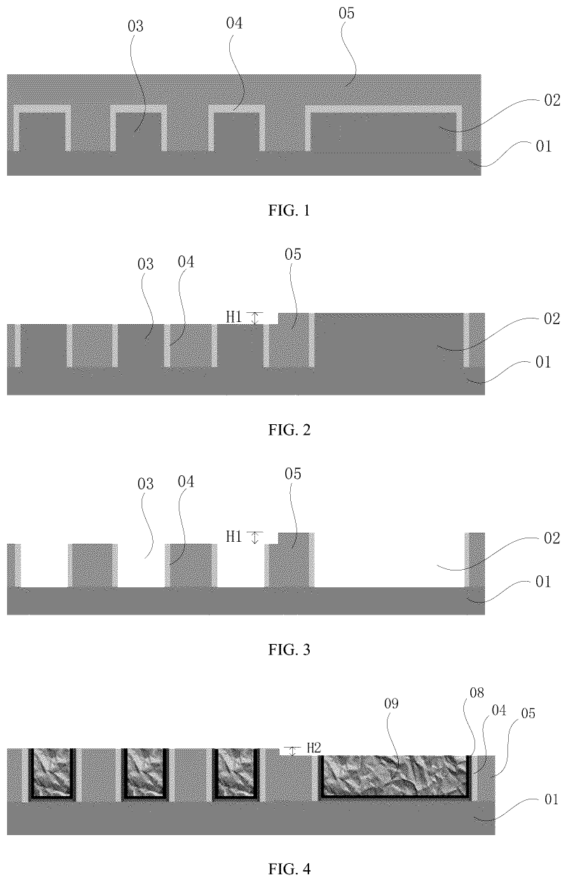

Please refer to FIG. 1 to FIG. 5. It should be noted that the drawings provided in the embodiments only illustrate the basic concept of the present application in a schematic way, thus only illustrate the components related to the present application, and are not drawn according to the number, shape and size of the components in the actual implementation. The type, number and scale of each component in the actual implementation may be changed freely, and the layout configuration of the component may be more complex.

The present application provides a method for improving a height difference between gates. Referring to FIG. 5, it illustrates a flowchart of the method for improving the height difference between gates. The method at least includes the following steps:

In step 1, a silicon substrate is provided. Small-size dummy gate structures and large-size dummy gate structures adjacent to the small-size dummy gate structures are formed on the silicon substrate. The height of the small-size dummy gate structures is the same as the height of the large-size dummy gate structures. Then, a silicon nitride layer is formed on surfaces of the small-size dummy gate structures and the large-size dummy gate structures. Then, an interlayer dielectric layer is deposited on the silicon nitride layer on the small-size dummy gate structures and the large-size dummy gate structures. The interlayer dielectric layer fills gaps between the small-size dummy gate structures and the large-size dummy gate structures.

Referring to FIG. 1, it illustrates a cross sectional view of a structure of large-size dummy gate structures and small-size dummy gate structures on a substrate in the present application. In step 1, a silicon substrate 01 is provided. Small-size dummy gate structures 03 and large-size dummy gate structures 02 adjacent to the small-size dummy gate structures 03 are formed on the silicon substrate 01. The height of the small-size dummy gate structures 03 is the same as the height of the large-size dummy gate structures 02. Then, a silicon nitride layer 04 is formed on surfaces of the small-size dummy gate structures 03 and the large-size dummy gate structures 02. Then, an interlayer dielectric layer 05 is deposited on the silicon nitride layer 04 on the small-size dummy gate structures 03 and the large-size dummy gate structures 02. The interlayer dielectric layer 05 fills gaps between the small-size dummy gate structures 03 and the large-size dummy gate structures 02. In addition, an upper surface of the interlayer dielectric layer 05 is higher than an upper surface of the silicon nitride layer 04 located at the tops of the large-size dummy gate structures 02 and the small-size dummy gate structures 03.

Further, in this embodiment of the present application, in step 1, the dimension of the small-size dummy gate structures is less than 200 nm; the dimension of the large-size dummy gate structures is more than 200 nm. In the present application, dimension refers to critical dimension.

Further, in this embodiment of the present application, referring to FIG. 1, in step 1, the number of the small-size dummy gate structures 03 and the large-size dummy gate structures 02 is respectively a plurality (the number of the large-size dummy gate structures 02 in FIG. 1 is one, but the number of the large-size dummy gate structures 02 is a plurality in the actual process), and the plurality of small-size dummy gate structures 03 are spaced, the plurality of large-size dummy gate structures 02 are spaced, and the plurality of small-size dummy gate structures 03 are located on one side of the plurality of large-size dummy gate structures 02. That is to say, all the small-size dummy gate structures in this embodiment are located on one side of all the large-size dummy gate structures.

Further, in this embodiment of the present application, in step 1, the small-size dummy gate structures 02 and the large-size dummy gate structures 03 are formed of polysilicon.

In step 2, the interlayer dielectric layer is polished until the top surface of the large-size dummy gate structures is higher than the top surface of the small-size dummy gate structures by H1, the H1 is approximately 110 Å; Referring to FIG. 2, it illustrates a cross sectional view of a structure after the interlayer dielectric layer is polished in step 2 in the present application. In step 2, the interlayer dielectric layer 05 is polished until the top surface of the large-size dummy gate structures 02 is higher than the top surface of the small-size dummy gate structures 03 by H1, the H1 is approximately 110 Å. Step 2 is mainly to polish the interlayer dielectric layer. After the interlayer dielectric layer at the tops of the large-size dummy gate structures and the small-size dummy gate structures is removed, the large-size dummy gate structures and the small-size dummy gate structures will be polished, and the interlayer dielectric layer between the plurality of small-size dummy gate structures and the interlayer dielectric layer between the plurality of large-size dummy gate structures will be continuously polished. Therefore, according to the characteristics of chemical-mechanical polishing when used for polishing the InterLayer Dielectric (ILD) layer, if the interlayer dielectric layer, the large-size dummy gate structures and the small-size dummy gate structures are polished simultaneously, the polishing speed of the large-size dummy gate structures is less than the polishing speed of the small-size dummy gate structures. Therefore, in the polishing process, the height of the large-size dummy gate structures will be caused to be more than the height of the small-size dummy gate structures. When the height difference H1 of the two is approximately 110 Å, the polishing is stopped.

Further, in this embodiment of the present application, in step 2, a method for polishing the interlayer dielectric layer 05 is a chemical-mechanical polishing method.

In step 3, the small-size dummy gate structures and the large-size dummy gate structures are removed to form large-size trenches and small-size trenches. The height of the silicon nitride layer on sidewalls of the large-size trenches and the small-size trenches is the same as the height of the adjacent interlayer dielectric layer. Referring to FIG. 3, it illustrates a cross sectional view of a structure after large-size dummy gate structures and small-size dummy gate structures are removed in the present application. In step 3, the small-size dummy gate structures and the large-size dummy gate structures are removed to form large-size trenches 07 and small-size trenches 06. The height of the silicon nitride layer 04 on sidewalls of the large-size trenches 07 and the small-size trenches 06 is the same as the height of the adjacent interlayer dielectric layer (the interlayer dielectric layer 05 after polishing in step 2).

Further, in this embodiment of the present application, in step 3, the dimension of the large-sized trenches is more than 200 nm; the dimension of the small-size trenches is less than 200 nm.

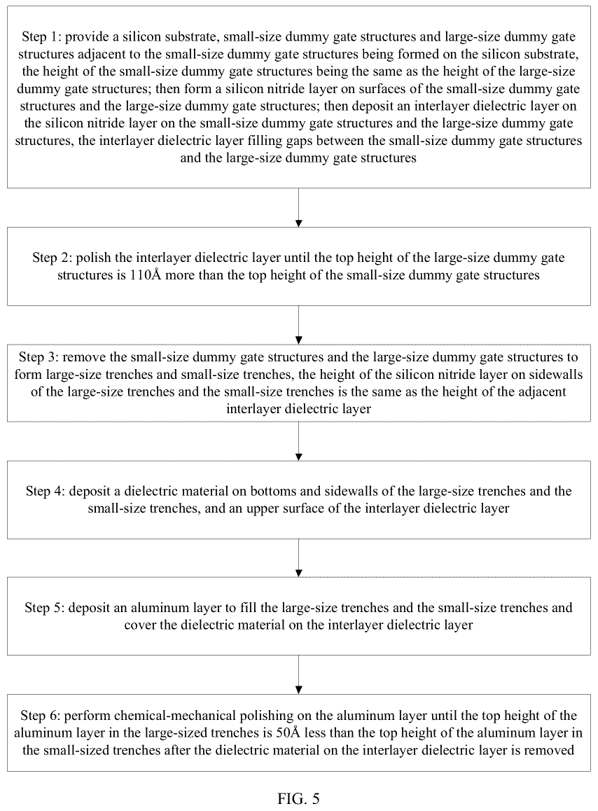

In step 4, a dielectric material is deposited on bottoms and sidewalls of the large-size trenches and the small-size trenches, and an upper surface of the interlayer dielectric layer. Referring to FIG. 4, it illustrates a cross sectional view of a structure of metal gates formed in large-size trenches and small-size trenches in the present application. In step 4, a dielectric material 08 is deposited on bottoms and sidewalls of the large-size trenches and the small-size trenches, and an upper surface of the interlayer dielectric layer 05.

Further, in this embodiment of the present application, in step 4, the dielectric material 08 includes tungsten.

In step 5, an aluminum layer is deposited to fill the large-size trenches and the small-size trenches and cover the dielectric material on the interlayer dielectric layer. In this step, the filled aluminum layer covers the tops of all large-size trenches, small-size trenches and interlayer dielectric layer.

In step 6, chemical-mechanical polishing is performed on the aluminum layer until the top surface of the aluminum layer in the large-sized trenches is lower than the top surface of the aluminum layer in the small-sized trenches by H2 after the dielectric material on the interlayer dielectric layer is removed, the H2 is approximately 50 Å. Referring to FIG. 4, in step 6, chemical-mechanical polishing is performed on the aluminum layer 09 until the op surface of the aluminum layer 09 in the large-sized trenches is lower than the top surface of the aluminum layer in the small-sized trenches by H2 after the dielectric material 08 on the interlayer dielectric layer is removed, the H2 is approximately 50 Å. In FIG. 4, the height difference H2 between the two is 50 Å. Due to the different polishing speeds of large-size aluminum gates and small-size aluminum gates, when the aluminum layer in the large-size trenches and the aluminum layer in the small-size trenches are polished simultaneously, the polishing speeds of the two are different. The top of the aluminum layer in the large-size trenches is polished faster, and the top of the aluminum layer in the small-size trenches is polished more slowly. Since the height of the large-size dummy gate structures in step 2 is more than the height of the small-size dummy gate structures, after polishing in step 6, the height difference between the top surface of the aluminum layer 09 in the large-size trenches and the top surface of the aluminum layer in the small-size trenches can be controlled at 50A, thus greatly reducing the height difference between the two and improving the device performance.

In step 6, after the chemical-mechanical polishing is performed on the aluminum layer, the aluminum layer, the dielectric material and the silicon nitride layer in the large-size trenches form large-size metal gates; the aluminum layer, the dielectric material and the silicon nitride layer in the small-size trenches form small-size metal gates.

Further, in this embodiment of the present application, in step 6, after the polishing is performed, the heights of the large-size metal gates are approximately 361 Å; and the heights of the small-size metal gates are approximately 415 Å.

To sum up, in the present application, by polishing the interlayer dielectric layer to enable the height of the large-size dummy gates to be 100 Å more than the height of the small-size dummy gates, since the height of the metal gates to be designed is not continuously reduced in the dummy gate removal process, no pit is caused between the upper surface of the remaining interlayer dielectric layer and the adjacent silicon nitride layer, thus shortening the subsequent polishing time of the metal gates, reducing the height difference between the large-size metal gates and the small-size metal gates, and helping to improve the device performance. Therefore, the present application effectively overcomes various disadvantages in the existing technology and has a high industrial utilization value.

The above embodiments are only used for exemplarily describing the principle and effect of the present application, instead of limiting the present application. Those skilled in the art may modify or change the above embodiments without departing from the spirit and scope of the present application. Therefore, all equivalent modifications or changes made by those with ordinary knowledge in the technical field without departing from the spirit and technical concept disclosed in the present application should still be covered by the claims of the present application.

What is claimed is:

1. A method for improving a height difference between gates, wherein the method at least comprises:
step 1: providing a silicon substrate,
forming small-size dummy gate structures and large-size dummy gate structures on the silicon substrate, wherein the large-size dummy gate structures are disposed adjacent to the small-size dummy gate structures, wherein heights of the small-size dummy gate structures and heights of the large-size dummy gate structures are equal;
forming a silicon nitride layer on surfaces of the small-size dummy gate structures and on surfaces of the large-size dummy gate structures;
depositing an interlayer dielectric layer on the silicon nitride layer over the small-size dummy gate structures and the large-size dummy gate structures, wherein the interlayer dielectric layer fills gaps between adjacent the small-size dummy gate structures and the large-size dummy gate structures;
step 2: polishing the interlayer dielectric layer until top surfaces of the large-size dummy gate structures are higher than top surfaces of the small-size dummy gate structures by H1;
step 3: removing the small-size dummy gate structures and the large-size dummy gate structures to form large-size trenches and small-size trenches, wherein a height of the silicon nitride layer on sidewalls of the large-size trenches and a height of the silicon nitride layer on sidewalls of the small-size trenches, and a height of an adjacent interlayer dielectric layer are equal;
step 4: depositing a dielectric material on bottoms and the sidewalls of the large-size trenches and the small-size trenches, and also a top surface of the interlayer dielectric layer;
step 5: depositing an aluminum layer to fill the large-size trenches and the small-size trenches and to cover the dielectric material on the top surface of the interlayer dielectric layer; and
step 6: performing chemical-mechanical polishing on the aluminum layer until a top surface of the aluminum layer in the large-sized trenches is lower than a top surface of the aluminum layer in the small-sized trenches by H2 after the dielectric material on the interlayer dielectric layer is removed.

2. The method for improving the height difference between gates according to claim 1, wherein in step 1, a dimension of the small-size dummy gate structures is less than 200 nm; a dimension of the large-size dummy gate structures is more than 200 nm, and wherein the H1 is approximately 110 Å, and the H2 is approximately 50 Å.

3. The method for improving the height difference between gates according to claim 2, wherein in step 1, a number of the small-size dummy gate structures and a number of the large-size dummy gate structures are respectively plurals, wherein the small-size dummy gate structures are spaced apart, the large-size dummy gate structures are spaced apart, and wherein the small-size dummy gate structures are arranged at one side of the large-size dummy gate structures.

4. The method for improving the height difference between gates according to claim 1, wherein in step 1, the small-size dummy gate structures and the large-size dummy gate structures are formed of polysilicon.

5. The method for improving the height difference between gates according to claim 1, wherein in step 2, a method for polishing the interlayer dielectric layer is a chemical-mechanical polishing method.

6. The method for improving the height difference between gates according to claim 1, wherein in step 3, the dimensions of the large-sized trenches are more than 200 nm; and the dimensions of the small-size trenches are less than 200 nm.

7. The method for improving the height difference between gates according to claim 1, wherein in step 4, the dielectric material comprises tungsten.

8. The method for improving the height difference between gates according to claim 1, wherein in step 6, after the chemical-mechanical polishing is performed on the aluminum layer, the aluminum layer, the dielectric material and the silicon nitride layer in the large-size trenches form large-size metal gates, and wherein the aluminum layer, the dielectric material and the silicon nitride layer in the small-size trenches form small-size metal gates.

9. The method for improving the height difference between gates according to claim 8, wherein in step 6, after the chemical-mechanical polishing is performed, heights of the large-size metal gates are approximately 361 Å, and heights of the small-size metal gates are approximately 415 Å.
